(19) United States
(12) Patent Application Publication
(10) Pub. No.: US 2008/0070520 A1
(43) Pub. Date: Mar. 20, 2008

(54) Method And Apparatus For Improving Efficiency Of RF Power Amplifier Using A Power Converter With An Exponential Transfer Function

(76) Inventors: Chang Su Mitter, Phoenix, AZ (US); Thomas J. Karpus, Cary, NC (US); Azhar Din, Dalloch (GB)

Correspondence Address: O'Melveny & Myers LLP;IP&T Calendar Department LA-1118, 400 South Hope Street, Los Angeles, CA, 90071-2899, US

(21) Appl. No.: 11/775,822

(22) Filed: Jul. 10, 2007

Related U.S. Application Data
(63) Continuation of application No. 11/550,380, filed on Oct. 17, 2006, now abandoned.
(60) Provisional application No. 60/727,741, filed on Oct. 17, 2005.

(51) Int. Cl. H04B 1/04; H03G 3/20

(52) U.S. Cl. 455/127.2; 330/129

(57) ABSTRACT

Methods and apparatuses are provided for achieving efficient power usage by a power amplifier. For example, there is provided an apparatus comprising: a processor unit providing one or more processor outputs, one of the processor outputs comprising a control voltage; and a variable gain amplifier operatively coupled to the processor and the power amplifier, wherein the variable gain amplifier comprises a piecewise linear circuit that receives the control voltage from the processor unit and provides a supply voltage to the power amplifier. In one embodiment, the processor unit is operatively coupled to a receiver that receives a feedback signal via radio link from a remote base station. The piecewise linear circuitry adjusts the supply voltage to the power amplifier at an exponential rate according to power requirements of the power amplifier.

### RELATED APPLICATION DATA

This application is a continuation pursuant to 35 U.S.C. §120 of U.S. patent application Ser. No. 11/550,380, filed Oct. 17, 2006, which claims the benefit pursuant to 35 U.S.C. §119(e) of U.S. provisional application Ser. No. 60/727,741, filed Oct. 17, 2005.

### BACKGROUND OF THE INVENTION

1. Field of the Invention

The present invention relates to switching mode power converter circuits, and more particularly, to a method and apparatus for using switching mode power converter circuits to provide efficient power use by a power amplifier.

2. Description of Related Art

The latest generation of communication devices, such as third generation (3G) mobile phones, provide more data transmission capabilities than their predecessors. Mobile phones usually include an RF power amplifier (PA) that generates the transmit power required to communicate with a base station. Some of the latest data transmission applications, such as on-line gaming, data web surfing, and the like, require the RF power amplifier to operate more frequently than they would for an ordinary voice call. As a result, the RF power amplifier tends to consume more current and the battery tends to run down (i.e., discharge) more quickly. It is, therefore, desirable to increase the efficiency of the phone circuitry (i.e., reduce current consumption) so as to maximize battery life.

One known method for reducing current consumption is to adaptively control the power supplied to the RF power amplifier. Adaptive power supply control is achieved by varying the supply voltage level based on the power requirements of the power amplifier. For example, if the power amplifier is at maximum power, the power supply would be set to its highest level (i.e., equal to the battery voltage) so that the power amplifier is not power limited. Conversely, during transmission periods in which lower power levels are required, the adaptive controller can decrease the input voltage to the power amplifier in order to maintain the maximum efficiency in the power amplifier while drawing less battery current.

A common technique for increasing efficiency while decreasing the supply voltage involves using a switch-mode step-down (buck) DC-DC converter as the power supply. A buck converter provides a regulated DC output voltage to a load by alternately using the input supply and an inductor to supply load current. When the supply is connected to the load, current passes through an inductor which stores energy at the same time. When the supply is disconnected, another switch from ground to the input of inductor is connected, allowing the inductor to discharge its stored energy and supply current to the load. The amount of time each phase of operation takes place depends on the desired output voltage. The total time the supply is connected is determined by the ratio of the desired voltage to the actual supply voltage. For example, if the supply is 5V and the desired supply is 2.5V, then the supply will only be connected for 50% of the total time. During the second 50% of any period, the load is supplied by the discharging inductor. To reduce voltage ripple, a capacitor is added to the output of the inductor to form a low pass filter.

In conventional mobile phone circuitry using Code Division Multiple Access (CDMA) standards, the handset battery is typically connected directly to the power amplifier. Newer designs have inserted a buck converter to reduce the PA supply voltage while improving system efficiency. These converters typically provide a linear transfer function that takes an analog input control signal and generates an output supply voltage using a fixed gain constant. Such systems typically require the system processor to use a look-up table to match the control signal to the desired output voltage for the desired RF output power level. Using a converter like this can involve complex software development and other related steps, which makes this approach less than optimal from the standpoint of efficiency.

CDMA PAs need to have excellent linearity, so their voltage requirements for optimal efficiency typically follow a nonlinear relationship with respect to output power. Accordingly, it would be very desirable to provide an improved method and apparatus for improving PA system efficiency that takes into consideration the non-linear voltage requirements of CDMA PAs.

### SUMMARY OF THE INVENTION

The present invention overcomes the shortcomings of the prior art by providing a method and apparatus for measuring output current and power in real-time for a CPU core powered by a DC-to-DC power converter having active voltage positioning.

In accordance with one aspect of the embodiments described herein, there is provided a system for optimizing PA system efficiency that uses the same power control signal that the transmitter uses to set the output power level to determine the optimal supply voltage. Such a system could employ a buck converter with an exponential transfer function instead of linear to match a PA's power requirements to the expected transmit control signal, thereby optimizing efficiency while eliminating the need to develop additional software and look-up tables.

In an embodiment of the invention, a switched mode power converter comprises at least one power switch operatively coupled to an input voltage source, an output filter operatively coupled to the at least one power switch to provide an output voltage and output current to a load, and a control circuit coupled to the at least one power switch. The control circuit activates the power switch with a duty cycle controlled to regulate at least one of the output voltage and the output current. The control circuit receives a first control signal defining a desired value for the output voltage, a second control signal defining a relationship between voltage input and current draw for the load, and a voltage sense signal corresponding to an actual value of the output voltage. The control circuit thereby provides a measurement of load current in accordance with the following equation:
I_{LOAD}=(V_{DAC}−V_{OUT})/_{AVP}_{SLOPE}
wherein, V_{DAC} is the desired output voltage, V_{OUT} is the voltage sense signal, AVP_{SLOPE} is the slope of the load-line signal, and I_{LOAD} is the load current.

In another embodiment of the invention, a method for monitoring load current drawn by a microprocessor comprises the steps of (a) providing a regulated output voltage and output current to the microprocessor, (b) receiving a first control signal defining a desired value for the output voltage, a second control signal defining a relationship between voltage input and current drawn by the microprocessor, and a voltage sense signal corresponding to an actual value of the output voltage, and (c) deriving the microprocessor load current in accordance with the equation set forth above.

In accordance with another aspect of the embodiments described herein, there is provided an apparatus for controlling power usage by a power amplifier, comprising: a processor unit providing one or more processor outputs, one of the processor outputs comprising a control voltage; and a variable gain amplifier operatively coupled to the processor and the power amplifier. In one embodiment, the variable gain amplifier comprises a piecewise linear circuit that receives the control voltage from the processor unit and provides a supply voltage to the power amplifier. The piecewise linear circuitry preferably adjusts the supply voltage to the power amplifier at an exponential rate according to power requirements of the power amplifier.

In accordance with another aspect of the embodiments described herein, there is provided a method for controlling power usage by a power amplifier to achieve efficient power usage, comprising: providing a control voltage to a variable gain amplifier operatively coupled to the power amplifier; providing a supply voltage from the variable gain amplifier to the power amplifier, the supply voltage having a supply voltage power level based at least in part on the control voltage; and receiving a feedback signal representing power requirements of the power amplifier. The method further comprises adjusting the control voltage based according to the received feedback signal; and adjusting the supply voltage power level to the power amplifier at an exponential rate according to the adjusted control voltage.

In accordance with another aspect of the embodiments described herein, there is provided a system for controlling power usage in a mobile phone, comprising: a processor unit providing one or more processor outputs, one of the processor outputs comprising a control voltage signal; a variable gain amplifier operatively coupled to the processor to receive the control voltage signal; and a power amplifier operatively coupled to the variable gain amplifier to receive a supply voltage signal from the variable gain amplifier. In one embodiment, the variable gain amplifier adjusts the supply voltage to the power amplifier at an exponential rate according to power requirements of the power amplifier.

In accordance with yet another aspect of the embodiments described herein, there is provided a processor readable recording medium for storing instructions that makes a processor execute: provide a control voltage signal to a variable gain amplifier operatively coupled to a power amplifier, the control voltage signal controlling at least in part a supply voltage signal from the variable gain amplifier to the power amplifier; receive a feedback signal representing power requirements of the power amplifier; and adjust the control voltage signal based on the received feedback signal to adjust power level of the supply voltage signal to the power amplifier at an exponential rate.

A more complete understanding of the method and apparatus for achieving efficient power usage by a power amplifier of a communication device will be afforded to those skilled in the art, as well as a realization of additional advantages and objects thereof, by a consideration of the following detailed description of the preferred embodiment. Reference will be made to the appended sheets of drawings, which will first be described briefly.

### BRIEF DESCRIPTION OF THE DRAWINGS

FIG. 1 is a schematic block diagram of an embodiment of a mobile phone transmit line;

FIG. 2 are graphs showing an ideal exponential transfer function and an piece-wise linear transfer function used to approximate the exponential transfer function;

FIG. 3 is a schematic block diagram of an embodiment of a bandgap reference cell used to produce a plurality of reference voltages;

FIG. 4 is a schematic block diagram of an embodiment of an individual current steering element;

FIG. 5 is a graph showing an idealized transfer function for the current steering element of FIG. 4;

FIG. 6 is a schematic block diagram of a plurality of current steering elements operatively coupled to a common resistor;

FIG. 7 is a graph illustrating a piece-wise linear transfer function produced by the plurality of current steering elements of FIG. 6; and

FIG. 8 is an exemplary schematic diagram of a power converter control circuit that provides an approximate exponential transfer function in accordance with an embodiment of the invention.

### DETAILED DESCRIPTION OF THE PREFERRED EMBODIMENT

The present invention satisfies the need for a power converter that has an exponential transfer function to obtain greater efficiency from the RF power amplifier of a CDMA mobile phone.

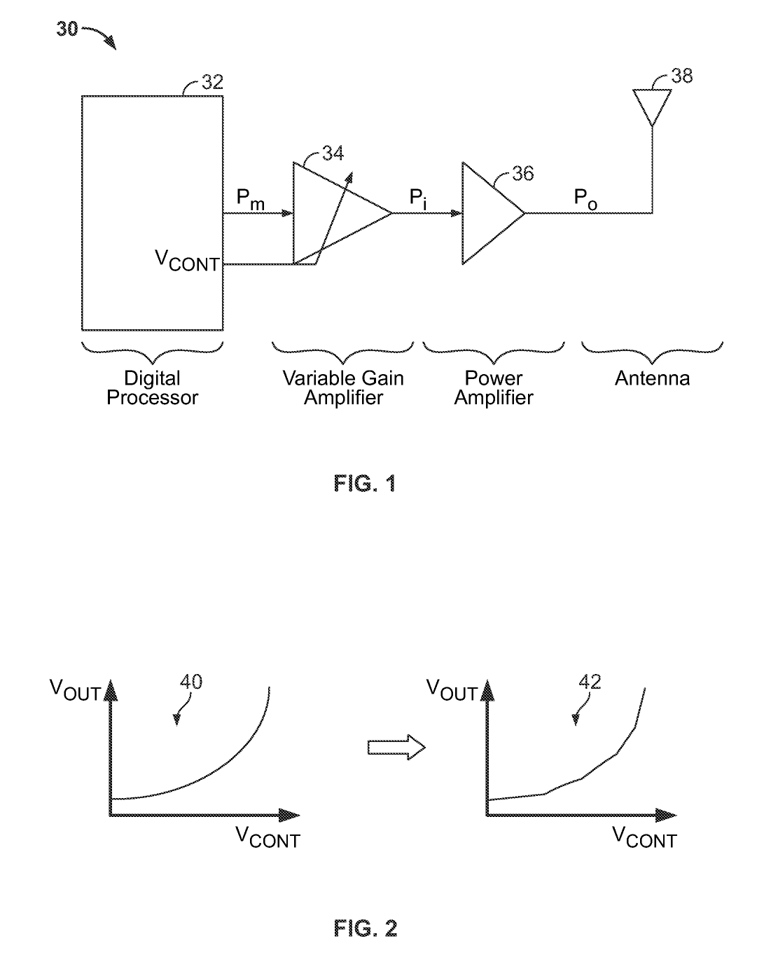

FIG. 1 illustrates a schematic block diagram of a mobile phone transmit line 30 including a digital processor 32, a variable gain amplifier 34, a power amplifier 36, and an antenna 38. The digital processor 32 provides a signal Pₘ to be transmitted by the mobile phone. The signal Pₘ has a fixed amplitude. The processor 32 provides a control voltage V_{cont} that determines the gain of the variable gain amplifier 34. The variable gain amplifier 34 amplifies the signal Pₘ by the variable gain determined by the control voltage V_{cont} and provides an input signal to the power amplifier 36 having power level Pᵢ. The power amplifier 36 further amplifies the signal and provides an output signal having power level Pₒ. The amplified signal is thereafter provided to the antenna 38, which radiates the amplified signal for eventual receipt by a base station.

The mathematical relationship between the output voltage amplitude of the variable gain amplifier and the control voltage V_{cont} is represented by the following equation:
Vₒᵤₜ=A×e^{B×V}^{_{cont}}^{+C}+D
where A, B, C and D are constants for a particular system design. This equation shows that the output voltage signal amplitude is a logarithmic function of the gain control voltage V_{cont}. The output power level Pₒ is calibrated to meet a certain level of accuracy in order to satisfy type approval for certain wireless communication standards. In other words, the relationship between the output power level Pₒ and the control voltage is made to fit the relationship defined by the foregoing equation.

In order to maintain linearity and efficiency, the supply voltage Vₛ to the power amplifier must track the signal amplitude in accordance with the following equation:
Vₛ=x×Vₒᵤₜ
in which x is chosen to maintain the highest efficiency without failing the linearity requirements. By combining the foregoing two equations, the relationship between the power amplifier supply voltage Vₛ and the control voltage V_{cont} may be obtained, as follows:
Vₛ=x×A×e^{B×V}^{_{cont}}^{+C}+D
In accordance with an embodiment of the invention, the variable gain amplifier is constructed to exhibit this non-linear relationship between the power amplifier supply voltage Vₛ and the control voltage V_{cont}. This leads to longer battery life in comparison to conventional systems using a variable gain amplifier having a fixed or linear relationship between the power amplifier supply voltage Vₛ and the control voltage V_{cont}.

FIG. 2 illustrates in graphical form an ideal exponential transfer function 40 and a piece-wise linear transfer function 42 used to approximate the exponential transfer function. The graph 40 on the left illustrates an ideal exponential transfer function. In order to approximate the exponential transfer function, the graph 42 on the right uses a piece-wise linear technique to construct a curve from a plurality of line segments. The accuracy of the piece-wise linear transfer function 42 in approximating the exponential transfer function 40 is determined by the number of segments and the linearity of each segment.

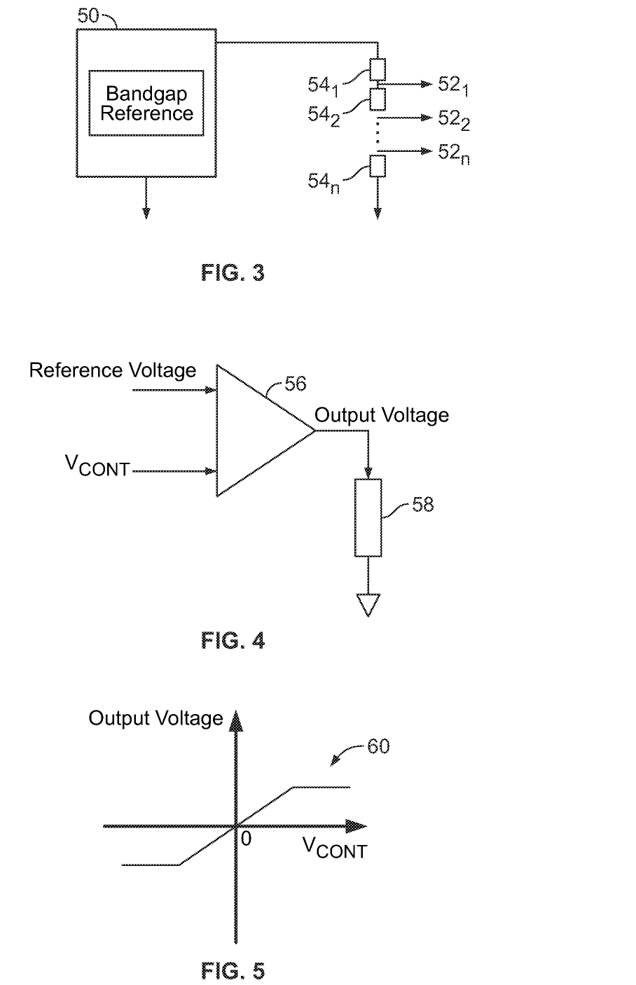

FIG. 3 illustrates a bandgap reference cell 50 hat is used to generate a plurality of reference voltage levels 52₁, 52₂, . . . 52ₙ. The bandgap reference cell 50 provides a reference voltage 52 to a plurality of serially coupled resistors 54₁, 54₂, . . . 54ₙ. The resistors (54₁, 54₂, . . . 54ₙ) divide the bandgap reference voltage into a plurality of successive reference voltages (52₁, 52₂, . . . 52ₙ). The reference voltages (52₁, 52₂, . . . 52ₙ. are in turn applied to respective current steering cells, such as the current steering cell 56 illustrated in FIG. 4. The exemplary current steering cell 56 receives as inputs a reference voltage 52 from the bandgap reference cell 50 and the control voltage V_{cont}. In one embodiment, the current steering cell 56 produces a current if the reference voltage 52 is close to, i.e., within a predetermined range or margin of error of, the control voltage V_{cont}, as reflected by the transfer function 60 illustrated in FIG. 5.

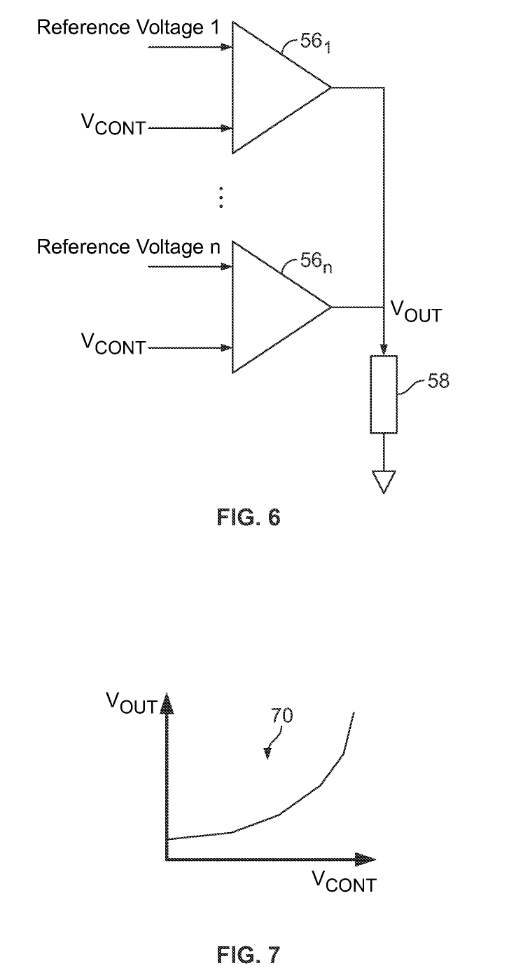

As shown in FIG. 6, a plurality of like current steering cells (56₁, 56₂, . . . 56ₙ) are coupled to a common resistor 58. Accordingly, the output voltage Vₒᵤₜ across the common resistor 58 varies with respect to the control voltage V_{cont} in accordance with the transfer function 70 shown in FIG. 7, which approximates the ideal exponential transfer function. The output voltage Vₒᵤₜ may then be used as a reference to a conventional DC-to-DC converter that is optimized to meet the requirements of the intended application, i.e., to provide power supply voltage to a power amplifier in a wireless system.

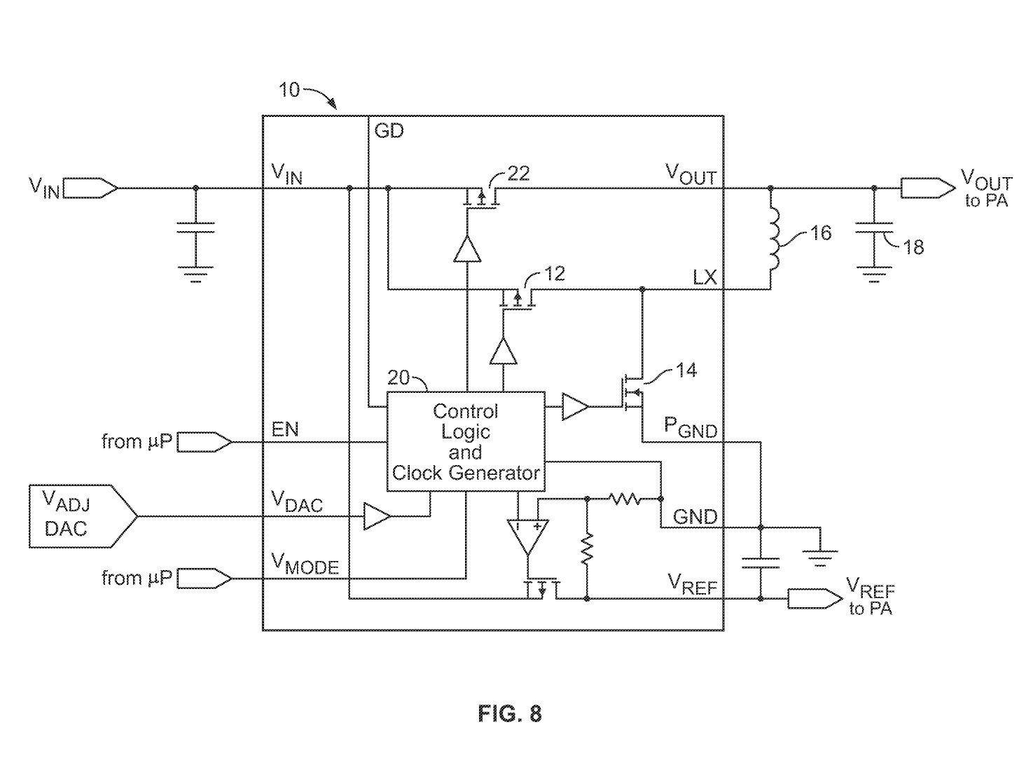

Referring now to FIG. 8, an exemplary DC-to-DC power converter control circuit 10 provides an approximate exponential transfer function in accordance with an embodiment of the invention. The DC-to-DC power converter 10 corresponds to the variable gain amplifier of FIG. 1, and provides an output voltage (V_{OUT}) to a power amplifier. The DC-to-DC power converter 10 further includes a high-side power switch 12 and a low-side power switch 14 connected to an input voltage source (V_{IN}). The high-side power switch 12 and the low-side power switch 14 are generally provided by MOSFET devices, with the source of high-side power switch 12 electrically connected to the input voltage source V_{IN}, the drain of the high-side power switch 12 electrically connected to the drain of the low-side power switch 14, and the source of the low-side power switch 14 electrically connected to ground. A power phase node is defined between the source of the high-side power switch 12 and the drain of the low-side power switch 14. An output inductor 16 is connected in series between the power phase node and the load. A capacitor 18 is electrically connected in parallel with the load to provide smoothing of the output voltage V_{OUT}. A control circuit 20 is connected to the gates of both the high-side power switch 12 and low-side power switch 14 through suitable drivers, and generates a series of pulse width modulated control pulses for the power switches 12, 14 to regulate the output voltage V_{OUT} coupled to the load. The control circuit 20 provides a signal to turn on the power switches 12, 14 in an alternating manner. The control circuit 20 regulates the current through the output inductor 16 by controlling the timing and duration of conduction of the power switches 12, 14.

A bypass switch 22 enables the input voltage V_{IN} to be directly coupled to the output voltage V_{OUT}, so that power amplifier is at maximum power (i.e., output equal to the battery voltage). The control circuit 20 provides an activation signal to the bypass switch 22 through a suitable driver.

The control circuit 20 also provides the piecewise linear circuitry described above. The control circuit 20 receives two input signals from the digital processor that determine the output voltage V_{OUT}, including an analog control voltage V_{DAC} and a mode voltage V_{MODE}. The mode voltage V_{MODE} has a high and a low state corresponding to low and high power, respectively. In one embodiment, the control circuit 20 uses the analog control voltage V_{DAC} and mode voltage V_{MODE} to select the appropriate transfer function in accordance with the preceding description. The control circuit 20 then adjusts the duty cycle applied to the high and low side switches 12, 14 to change the output voltage V_{OUT} accordingly.

In accordance with another aspect of the embodiments described herein, there is provided a system comprising a processor unit, a variable gain amplifier operatively coupled to the processor unit, and a power amplifier operatively coupled to the variable gain amplifier to receive a supply voltage signal from the variable gain amplifier. The variable gain amplifier preferably adjusts the supply voltage to the power amplifier at an exponential rate according to the power requirements of the power amplifier. The system typically further comprises an antenna operatively coupled to the power amplifier to facilitate communicating with a remotely located base station.

In one embodiment, the system further comprises a receiver unit (e.g., receiver, transceiver, or the like) operatively coupled to the processor unit. The receiver unit can receive a feedback signal from the base station via a radio link or the like. The feedback signal can comprise information relating to the power requirements of the power amplifier. The feedback signal can be used to adjust the supply voltage to the power amplifier, such as, for example, by adjusting a control voltage signal from the process unit to the variable gain amplifier. In another embodiment, an internal feedback signal is used (in conjunction with or in lieu of a radio link feedback signal) is used to adjust the supply voltage to the power amplifier. For example, the power amplifier can provide a feedback signal to the digital processor, which in turn adjusts the control voltage V_{CONT} to provide closed loop control over a DC-to-DC power converter or the like.

Having thus described a preferred embodiment of a method and apparatus for optimizing power amplifier system efficiency by using the same power control signal that the transmitter uses to set the output power level to determine the optimal supply voltage, it should be apparent to those skilled in the art that certain advantages of the within system have been achieved. It should also be appreciated that various modifications, adaptations, and alternative embodiments thereof may be made within the scope and spirit of the present invention. For example, certain switching mode power converter circuits have been presented in the context of mobile phones, but it should be apparent that many of the inventive concepts described above would be equally applicable for other communication devices and systems.

What is claimed is:

1. An apparatus for controlling power usage by a power amplifier, comprising:
a processor unit providing one or more processor outputs, one of the processor outputs comprising a control voltage; and
a variable gain amplifier operatively coupled to the processor and the power amplifier, the variable gain amplifier comprising a piecewise linear circuit that receives the control voltage from the processor unit and provides a supply voltage to the power amplifier;
wherein the piecewise linear circuitry adjusts the supply voltage to the power amplifier at an exponential rate according to power requirements of the power amplifier.

2. The apparatus as recited in claim 1, further comprising a receiver operatively coupled to the processor unit.

3. The apparatus as recited in claim 2, wherein the processor unit adjusts the control voltage according to a radio link feedback signal received by the receiver.

4. The apparatus as recited in claim 1, wherein the processor unit is operatively coupled to the power amplifier and adjusts the control voltage according to a feedback signal received from the power amplifier.

5. The apparatus as recited in claim 1, wherein the piecewise linear circuit comprises a bandgap reference cell to provide a plurality of reference voltages.

6. The apparatus as recited in claim 5, wherein the variable gain amplifier further comprises a plurality of current steering cells, each current steering cell receiving one of the reference voltages as a first input and the control voltage as a second input.

7. The apparatus as recited in claim 6, wherein each current steering cell produces an output current when the first and second inputs are within a predetermined range of each other.

8. The apparatus as recited in claim 6, wherein the current steering cells are operatively coupled to a common resistor such that an output voltage across the common resistor that varies according to the control voltage.

9. The apparatus as recited in claim 8, wherein the output voltage across the common resistor approximates an exponential transfer function.

10. The apparatus as recited in claim 8, wherein the variable gain amplifier further comprises a DC-to-DC power converter operatively coupled to the common resistor to convert the output voltage to the supply voltage.

11. The apparatus as recited in claim 10, wherein the DC-to-DC power converter provides an approximate exponential transfer function.

12. The apparatus as recited in claim 10, wherein:
the DC-to-DC power converter comprises a converter control circuit operatively coupled to a high-side power switch and a low-side power switch; and
the converter control circuit controls the timing and duration of conduction of the high-side and low-side power switches.

13. The apparatus as recited in claim 12, wherein the converter control circuit turns on the high-side and low-side power switches in an alternating manner.

14. A method for controlling power usage by a power amplifier, comprising:
providing a control voltage to a variable gain amplifier operatively coupled to the power amplifier;
providing a supply voltage from the variable gain amplifier to the power amplifier, the supply voltage having a supply voltage power level based at least in part on the control voltage;
receiving a feedback signal representing power requirements of the power amplifier;
adjusting the control voltage based according to the received feedback signal; and
adjusting the supply voltage power level to the power amplifier at an exponential rate according to the adjusted control voltage.

15. The method of claim 14, wherein receiving a feedback signal representing power requirements of the power amplifier comprises receiving the feedback signal from a remote base station via a radio link.

16. The method of claim 14, wherein receiving a feedback signal representing power requirements of the power amplifier comprises receiving the feedback signal from the power amplifier.

17. The method of claim 14, wherein providing a control voltage to a variable gain amplifier comprises providing the control voltage to a piecewise linear circuit.

18. The method of claim 15, wherein providing the control voltage to a piecewise linear circuit comprises providing a bandgap reference cell to provide a plurality of reference voltages.

19. The method of claim 18, wherein providing the control voltage to a piecewise linear circuit further comprises providing a plurality of current steering cells, each current steering cell receiving one of the reference voltages as a first input and the control voltage as a second input.

20. The method of claim 19, wherein providing a plurality of current steering cells further comprises operatively coupling a DC-to-DC power converter to the common resistor to convert the output voltage to the supply voltage.

21. The method of claim 20, further comprising turning on high-side and low-side power switches of the DC-to-DC power converter in an alternating manner.

22. A system for controlling power usage in a mobile phone, comprising:
a processor unit providing one or more processor outputs, one of the processor outputs comprising a control voltage signal;
a variable gain amplifier operatively coupled to the processor to receive the control voltage signal; and
a power amplifier operatively coupled to the variable gain amplifier to receive a supply voltage signal from the variable gain amplifier;
wherein the variable gain amplifier adjusts the supply voltage to the power amplifier at an exponential rate according to power requirements of the power amplifier.

23. The system as recited in claim 22, further comprising a receiver operatively coupled to the processor unit.

24. The system as recited in claim 23, wherein the processor unit adjusts the control voltage according to a radio link feedback signal received by the receiver.

25. The system as recited in claim 22, wherein the processor unit is operatively coupled to the power amplifier and adjusts the control voltage according to a feedback signal received from the power amplifier.

26. The system as recited in claim 22, further comprising an antenna operatively coupled to the power amplifier.

27. The system as recited in claim 22, wherein the variable gain amplifier comprises a piecewise linear circuit.

28. The system as recited in claim 27, wherein the piecewise linear circuit comprises a bandgap reference cell to provide a plurality of reference voltages.

29. The system as recited in claim 28, wherein the variable gain amplifier further comprises a plurality of current steering cells, each current steering cell receiving one of the reference voltages as a first input and the control voltage as a second input.

30. The system as recited in claim 29, wherein each current steering cell produces an output current when the first and second inputs are within a predetermined range of each other.

31. The system as recited in claim 29, wherein the current steering cells are operatively coupled to a common resistor such that an output voltage across the common resistor that varies according to the control voltage.

32. The system as recited in claim 31, wherein the output voltage across the common resistor approximates an exponential transfer function.

33. The system as recited in claim 31, wherein the variable gain amplifier further comprises a DC-to-DC power converter operatively coupled to the common resistor to convert the output voltage to the supply voltage.

34. The system as recited in claim 33, wherein the DC-to-DC power converter provides an approximate exponential transfer function.

35. The system as recited in claim 33, wherein:
the DC-to-DC power converter comprises a converter control circuit operatively coupled to a high-side power switch and a low-side power switch; and
the converter control circuit controls the timing and duration of conduction of the high-side and low-side power switches.

36. The system as recited in claim 35, wherein the converter control circuit turns on the high-side and low-side power switches in an alternating manner.

37. A processor readable recording medium for storing instructions that makes a processor execute:
provide a control voltage signal to a variable gain amplifier operatively coupled to a power amplifier, the control voltage signal controlling at least in part a supply voltage signal from the variable gain amplifier to the power amplifier;
receive a feedback signal representing power requirements of the power amplifier; and
adjust the control voltage signal based on the received feedback signal to adjust power level of the supply voltage signal to the power amplifier at an exponential rate.
